(19) United States
(12) Patent Application Publication
(10) Pub. No.: US 2006/0202336 A1
(43) Pub. Date: Sep. 14, 2006

(54) Semiconductor device and method of fabricating a semiconductor device

(75) Inventors: Akihiro Kajita, Kanagawa-ken (JP); Masaki Yamada, Kanagawa-ken (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Minato-Ku (JP)

(21) Appl. No.: 11/360,659

(22) Filed: Feb. 24, 2006

(30) Foreign Application Priority Data
Feb. 25, 2005 (JP) 2005-051361

(51) Int. Cl. H01L 23/52

(52) U.S. Cl. 257/751

(57) ABSTRACT

A semiconductor device includes a semiconductor substrate, a first interconnection layer formed above the semiconductor substrate via a first interlayer insulating film, the first interconnection layer having Cu as a main material, a second interconnection layer formed above the first interlayer insulating film and the first interconnection layer via a second interlayer insulating film, and a via plug formed through the second interlayer insulating film, the via plug electrically connecting between the first interconnection layer and the second interconnection layer, wherein a first material being different from Cu is selectively included at a grain boundary beneath the via plug among a plurality of grain boundaries of the first interconnection layer.

### CROSS REFERENCE TO RELATED APPLICATION

This application is based upon and claims the benefit of priority from the prior Japanese Application No. 2005-051361, filed Feb. 25, 2005, the entire contents of which are incorporated herein by reference.

### FIELD OF THE INVENTION

The present invention relates to a semiconductor device having a plurality of metal interconnection layers and a via plug electrically connecting between the metal interconnection layers and to a method of fabricating the semiconductor device.

### DESCRIPTION OF THE BACKGROUND

Recently, miniaturization of interconnection layers and multilevel interconnections has proceeded with high integration and high performance of semiconductor devices. Suppression on RC delay of propagation signal also has been required for high speed operation of the semiconductor devices. To satisfy these requirements, for example, Japanese Unexamined Patent Publication (Kokai) No. 2003-257979 disclosed a method of using Cu having lower resistivity than that of Al as a material of an interconnection layer.

In a multilevel interconnection structure of Cu layers according to Japanese Patent Unexamined Publication (Kokai) No. 2003-257979, an interconnection groove for a first interconnection is formed in a first insulating film (a first interlayer insulating film). After forming a barrier metal layer on the first insulating film, a Cu film is embedded in the groove to form the first interconnection layer. After forming a second interlayer insulating film on the first interlayer insulating film and the first interconnection layer, an interconnection groove for a second interconnection layer and a through hole (a via hole) mutually connecting between the first interconnection layer and the second interconnection layer are formed in the second interlayer insulating film. After forming a barrier metal layer on the second insulating film, a Cu film is filled in the interconnection groove and the via hole to form the second interconnection layer and a via plug mutually connecting between the first interconnection layer and the second interconnection layer.

However, the semiconductor device having the Cu interconnection structure disclosed as a conventional technique has technical problems as described below. For example, stress migration on the Cu interconnection layer or the via plug causes connecting failure to lower reliability of the semiconductor device.

Stress migration can be categorized as two modes, for example, disclosed in M. kawano's “Stress Relaxation in Dual-damascene Cu interconnects to Suppress Stress-induced Voiding” (Proceedings of the 2003 International Interconnect Technology Conference 210-212, M. Kawano et al.).

First, a first mode of stress migration is explained. The first mode of stress migration is generated by weak adhesion strength of an interface between the barrier metal layer in the via hole and the second interconnection layer. After forming the second interconnection layer and the via plug, the Cu film filled in the via hole is pulled up by a heat treatment in processes or temperature rising in operations of the semiconductor device so as to generate a void between the first interconnection layer and the via plug. Accordingly, electrical connection between the first interconnection layer and the via plug is lost to cause a connecting failure between the first interconnection layer and the second interconnection layer.

Secondly, a second mode of stress migration is explained. When the interconnection groove and the via hole is formed in the second interlayer insulating film, an elevated portion of the first interconnection layer is formed at a bottom of the via hole because of various factors such as etching, temperature rising or the like. After forming the barrier metal layer in the interconnection groove and the via hole, the Cu film is filled in the interconnection groove and the via hole. After forming the second interconnection layer in the interconnection groove and the via plug in the via hole, a heat treatment is performed. In the above processes, the first interconnection layer is elastically or plastically deformed from a portion of the first interconnection layer located beneath the via plug as an origin so as to arise a crystalline imperfection such as strain or defects. The crystalline deterioration acts as a nucleus of void growth in heat treatments or temperature rising in the operations of the semiconductor device so as to generate a void at the portion of the first interconnection layer beneath the via plug. Accordingly, via resistance is increased up to over several ten times larger than a normal resistance, which leads to the connecting failure between the first interconnection layer and the second interconnection layer.

Rising the adhesion strength between the Cu interconnection layer and the barrier metal layer produces an improvement on the first mode of stress migration. The methods are, for example, using a metal having stronger adhesiveness to Cu as the barrier metal layer or inserting an adhesion layer like Ti between the Cu interconnection layer and the barrier metal layer. Moreover, the insulating film having low dielectric constant (low-k film) is often used as the interlayer insulating film for decreasing capacitance between interconnections in the Cu interconnection structure. Since the low-k film has high hygroscopic property, H₂O or the like emitted from the low-k film oxidized the barrier metal layer so as to lower adhesion strength between the Cu interconnection layer and the barrier metal layer. For improvement of the adhesion strength, for example, inserting a heat treatment as degassing between forming the via hole and forming the barrier metal layer in the via hole is effectively carried out.

In the second mode of stress migration, a crystalline deterioration is generated at a grain boundary in the portion of the Cu interconnection layer located beneath the via plug so that the crystalline deterioration acts as a nucleus of void growth in a heat treatment. Furthermore, various kinds of deformations are easily generated with increasing the heat treatment temperature to cause the crystalline deterioration. Since the Cu interconnection layer has a poly-crystalline structure, the portion located beneath the via plug has stochastically at least a Cu grain boundary.

A portion having low tolerance on the second mode of stress migration is inevitably in semiconductor devices fabricated by conventional technology. As described in the improvement of the first mode of stress migration, it is effective for increasing the adhesion strength between the Cu interconnection layer and the barrier metal layer to add comparatively a high temperature heat treatment step as degassing between forming the via hole and forming the barrier metal layer in the via hole and to form the metal in the via hole at comparatively a high temperature. However, the high temperature heat treatment step is not desired as the improvement of the second mode stress migration, therefore, the methods mentioned above still has technical problems.

### SUMMRY OF INVENTION

According to an aspect of the invention, there is provided a semiconductor device including, a semiconductor substrate, a first interconnection layer formed above the semiconductor substrate via a first interlayer insulating film, the first interconnection layer having Cu as a main material, a second interconnection layer formed above the first interlayer insulating film and the first interconnection layer via a second interlayer insulating film, and a via plug formed through the second interlayer insulating film, the via plug electrically connecting between the first interconnection layer and the second interconnection layer, wherein a first material being different from Cu is selectively included in a grain boundary beneath the via plug among a plurality of grain boundaries included in the first interconnection layer.

Further, according to another aspect of the invention, there is provided a method of fabricating semiconductor device including, forming a first interlayer insulating film above a semiconductor substrate, forming a first interconnection layer having Cu as a main material in the first interlayer insulating film, forming a second interlayer insulating film above the first interlayer insulating film and the first interconnection layer, forming an interconnection groove in the second interlayer insulating film and a via hole through the second interlayer insulating film to a surface of the first interconnection layer, the via hole being junctually formed to the interconnection groove, forming a thin film including a first material on an inner-wall of the interconnection groove, an inner-wall of the via hole and a surface portion of the first interconnection layer exposed in the via hole, the first material being different from Cu, diffusing the first material into a grain boundary of the first interconnection layer exposed in the via hole, forming a barrier metal layer on the thin film, and filling an interconnection material in the interconnection groove and the via hole via the barrier metal layer to form a second interconnection layer in the interconnection groove and a via plug in the via hole.

Further, according to another aspect of the invention, there is provided a method of fabricating semiconductor device including, forming a first interlayer insulating film above a semiconductor substrate, forming a first interconnection layer having Cu as a main material in the first interlayer insulating film, forming a second interlayer insulating film above the first interlayer insulating film and the first interconnection layer, forming a via hole through the second interlayer insulating film to a surface of the first interconnection layer, forming a thin film including a first material on an inner-wall of the via hole and a surface portion of the first interconnection layer exposed in the via hole, the first material being different from Cu, diffusing the first material into a grain boundary in a portion of the first interconnection layer exposed in the via hole, forming a barrier metal layer on the thin film, and forming a via plug in the via hole and a second interconnection layer above the second interlayer insulating film via the barrier metal layer.

### BRIEF DESCRIPTION OF THE DRAWINGS

FIG. 1 is a cross-sectional view showing a main portion of a semiconductor device according to a first embodiment of the present invention;

FIG. 2 is an enlarged cross-sectional view showing a first interconnection layer and a via plug of the semiconductor device according to the first embodiment of the present invention;

FIG. 3 is a schematically perspective view showing the first interconnection layer and the via plug of the semiconductor device according to the first embodiment of the present invention;

FIG. 4 is a cross-sectional view showing a main portion of the semiconductor device according to a modification on the first embodiment of the present invention;

FIGS. 5A to 5F are cross sectional views showing fabricating steps of the semiconductor device according to the first embodiment of the present invention;

FIG. 6 is a cross-sectional view showing a main portion of a semiconductor device according to a second embodiment of the present invention;

FIG. 7 is an enlarged cross-sectional view showing a first interconnection layer and a via plug of the semiconductor device according to the second embodiment of the present invention;

FIGS. 8A to 8G are cross sectional views showing fabricating steps of the semiconductor device according to the second embodiment of the present invention;

### DETAILED DESCRIPTION OF THE INVENTION

Embodiments of the present invention will be described hereinafter in detail with reference to the accompanying drawings mentioned above.

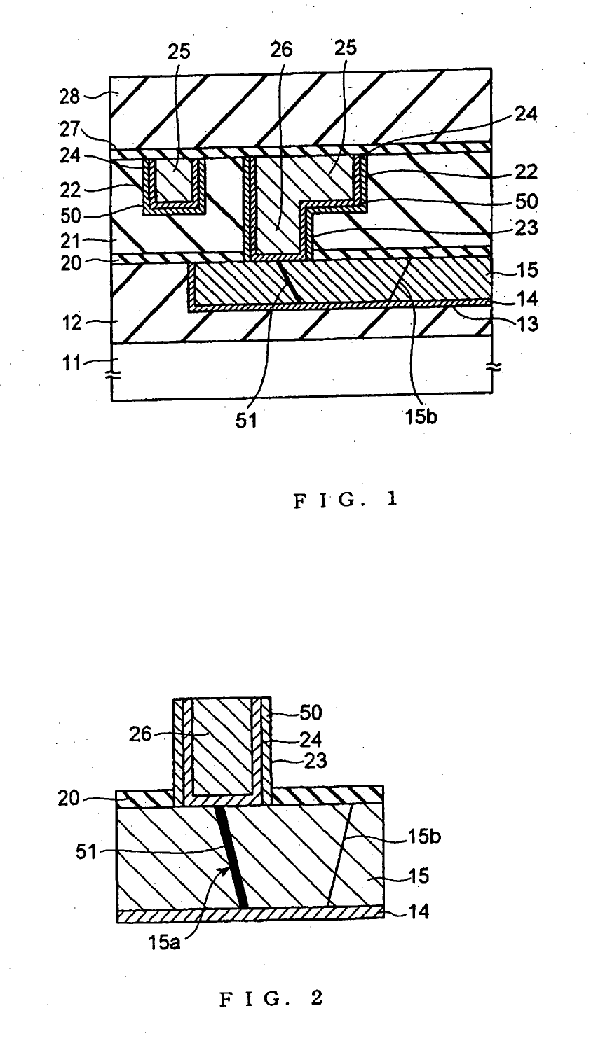

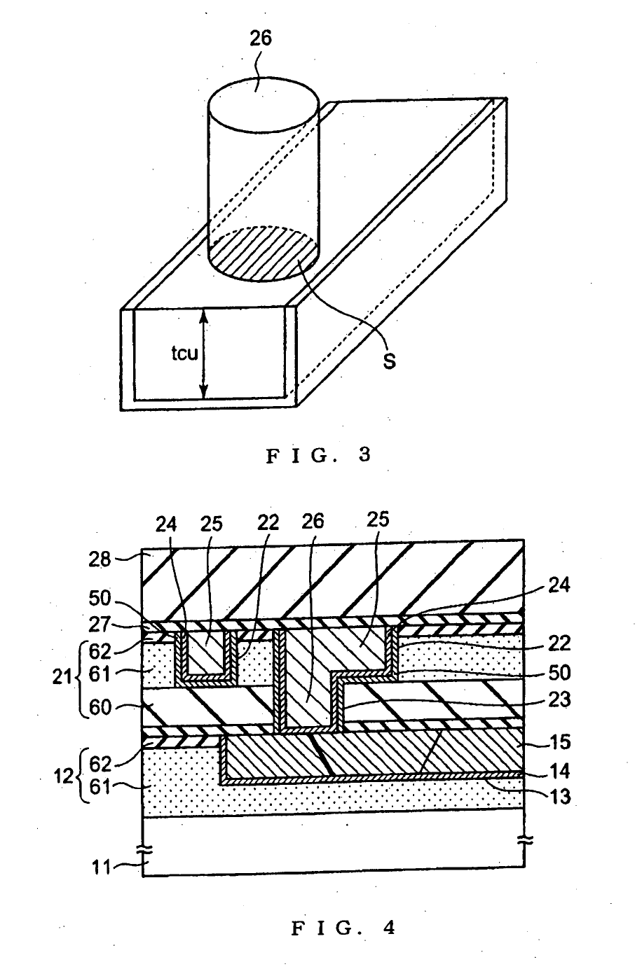

FIG. 1 is a cross-sectional view showing a main portion of a semiconductor device according to a first embodiment of the present invention. FIG. 2 and FIG. 3 are an enlarged cross-sectional view and an enlarged schematically perspective view, respectively, showing a first interconnection layer and a via plug in FIG. 1.

As shown in FIG. 1, a first interlayer insulating film 12 such as a SiOC film is formed above a semiconductor substrate 11 having a circuit element in the semiconductor device of this embodiment. An interconnection groove 13 is formed on the first interlayer insulating film 12. A first interconnection layer 15 composed of Cu is filled in the interconnection groove 13 via an under-layer barrier metal 14 such as Ta. The first interconnection layer 15 is electrically connected to the circuit element (not illustrated) in the semiconductor substrate 11.

A second interlayer insulating film 21 such as a SiOC film is formed on the first interlayer insulating film 12 and the first interconnection layer 15 via a first diffusion barrier insulating film 20 such as a silicon nitride film (SiN). An interconnection groove 22 for a second interconnection layer and a via hole 23 are formed in the second interlayer insulating film 21. The via hole 23 is juncturally formed to the interconnection groove 22 and is formed through the second interlayer insulating film 21 to the first interconnection layer 15.

A thin film 50 including a first material is formed on an inner side-wall of the interconnection groove 22, an inner side-wall of the via hole 23. The first material is diffused into a grain boundary in the first interconnection layer 15 as mentioned below. A barrier metal layer 24 such as Ta is formed on the thin film 50 and on a surface portion of the first interconnection layer 15 exposed on the bottom surface of the via hole 23.

A Cu film is filled on the barrier metal layer 24 in a interconnection groove 22 and the via hole 23 so as to form the second interconnection layer 25 composed of Cu in the interconnection groove 22. A via plug 26 composed of Cu is also formed in the via hole 23 for mutually connecting between the first interconnection layer 15 and the second interconnection layer 25.

An interlayer insulating film 28 is timely formed on the second interlayer insulating film 21 and the second interconnection layer 25 via a diffusion barrier insulating film 27. Moreover, a third interconnection layer and a fourth interconnection layer or the like (not illustrated) may be formed.

Since the first interconnection layer 15 is a poly-crystalline structure as shown in FIG. 2, the first interconnection layer 15 has a plurality of grain boundaries such as grain boundaries 15a, 15b. The grain boundary 15a in the grain boundaries is located beneath the via plug 26 in the via hole 23.

Crystalline quality of the grain boundary 15a is deteriorated by a heat treatment or the like. Accordingly, a void is grown to generate a connecting failure between the first interconnection layer 15 and the via plug 26. In order to solve the problem in this embodiment, the thin film 50 composed of the first material except Cu as the material of the interconnection layer 15, 25 and Ta as the material of the barrier metal layer 14, 24 is selectively diffused or included into the grain boundary 15a located in the portion of the first interconnection layer 15 exposed in the via hole 23. In this embodiment, an intermetallic compound 51 composed of the first material and Cu included in the first interconnection layer is formed in the grain boundary 15a.

A material having capability of forming an intermetallic compound with Cu as the material of the first interconnection layer 15 is selected as the first material being included in the grain boundary 15a. Therefore, the material used as the first material has solubility limit concentration to Cu at heat treatment temperatures, generally below 430° C., in forming the Cu interconnection layer and subsequent processes and has capability of forming the intermetallic compound above the solubility limit. For example, Al having approximately 19% atomic concentration as solubility limit to Cu, Si having approximately 8% atomic concentration as solubility limit to Cu and Mg having approximately 4% atomic concentration as solubility limit to Cu is the material corresponding to the first material. Since Al is used as the first material in this embodiment, processes mentioned below are explained on an Al film as the thin film.

When the first material 50 included in the first interconnection layer 15 beneath the via hole 23 is below solubility limit concentration, the intermetallic compound is not formed in crystal grains but formed in the grain boundary 15a. Here, the solubility limit concentration is defined as a solubility limit concentration at a prescribed temperature below 430° C. in diffusing the first material into the grain boundary. Therefore, the Al content supplied through the via hole 23 is given by
t_{Al}≦t_{Cu}·(C_{Cu}/C_{A})·α/(100−α) (1)

where t_{Al} is a thickness of the first material on a bottom surface of the second interconnection layer 25, t_{Cu} is a Cu thickness of the first interconnection layer 15, C_{Cu} and C_{A} are specific Cu atomic density and specific Al atomic density, respectively, α presented as percentage is the solubility limit concentration of the first material to Cu. Since the interconnection groove 22 is formed shallower than the via hole 23, the thickness t_{Al} of the Al thin film on the bottom surface of the second interconnection layer 25 is as a same as or thicker than the thickness of the Al thin film deposited on the bottom surface of the via hole 23 and subsequently supplied to the formation of the intermetallic compound. Accordingly, the intermetallic compound is not formed in the crystal grains under the condition of formula (1).

As shown in FIG. 3, the relationship of formula (1) means that a number of Al atoms supplied through the bottom surface of the via hole 23 is below solubility limit to a number of Cu atoms in V_{Cu}, where a square of the bottom surface of the via hole 23 is S, a volume of Cu in the portion of the first interconnection layer 15 beneath the via hole 23 is V_{Cu} (equal to S·t_{cu}). For example, when the bottom surface of the via plug 26 is a circle having a diameter of 10 nm and t_{cu} is 150 nm thick, t_{Al} of the Al thickness supplied through the bottom surface of the interconnection groove 22 is approximately below 50 nm thick.

Al arranged in the range described above is supplied on the first interconnection layer 15. The grain boundary 15a including crystalline defects on the bottom surface of the via hole 23 is selectively bonded with Al so as to reduce boundary energy. As a result, the Cu—Al intermetallic compound 51 is stably formed only at the grain boundary 15a. Since excess Al is below the solubility limit concentration to Cu, a Cu—Al intermetallic compound is not formed at a portion except the grain boundary 15a. Therefore, effective resistivity of the first interconnection layer 15 is not increased. Since the grain boundary 15a located beneath the via plug 26 is stable, the crystalline deterioration is not generated at the grain boundary 15a in heat treatment processes and in operations at high temperature, thus, the void growth is restrained. The problem on the connecting failure between the first interconnection layer 15 and the second interconnection layer 25 caused by stress migration can be eliminated by the above approach.

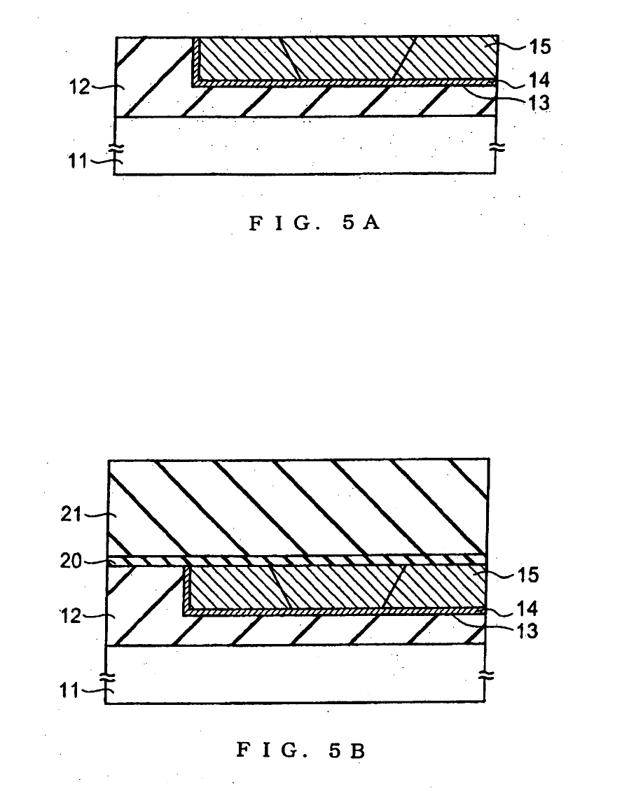

In this embodiment, SiOC is used as the first interlayer insulating film 12 and the second interlayer insulating film 21. However, the material of the interlayer insulating film is not limited the SiOC film but various kind of interlayer insulating films may be used such as a SiO₂ film, an organic film such as poly-methyl siloxane, poly-allylene ether or the like, a fluorinated organic film or a porous low-k film having introduced vacancies for obtaining lower dielectric constant. The interlayer insulating film can be formed by combination of the insulating materials as shown in FIG. 4. A portion of a same composition in FIG. 4 as shown in FIG. 1 is attached the same number, and explanation on the portion of the same composition is omitted. As shown in FIG. 4, a layered film of an organic film 61 and a SiO2 film 62 may be used as the first interlayer insulating film 12 and a layered film of a SiOC film 60, the organic film 61 and the SiO₂ film 62 may be used as the second interlayer insulating film 21

When a low-k film or the like having higher hygroscopic property and a porous low-k film having lower density are used for being decreased dielectric constant of the interlayer insulating film, H₂O in the low-k film and the porous low-k film may oxidize the barrier metal layer. The oxidation allows adhesion strength between the barrier metal layer and the Cu film to weaken. As a result, the connecting failure may be generated by the first mode of stress migration.

In this embodiment, as shown in FIG. 1 and FIG. 2, the thin film including the first material 50 is formed between the inner side-wall of interconnection groove 22 and the barrier metal layer 24 and between the via hole 23 and the barrier metal layer 24. Accordingly, oxidation of the barrier metal layer 24 is suppressed by the thin film 50. This technique sustains adhesion strength of an interface between the interconnection layer 25 and the via plug 26 composed of Cu, and the barrier metal layer 24. As a result, the problem on the connecting failure between the interconnections by the first mode of stress migration is eliminated without adding a heat treatment for degassing or inserting an adhesion layer or the like.

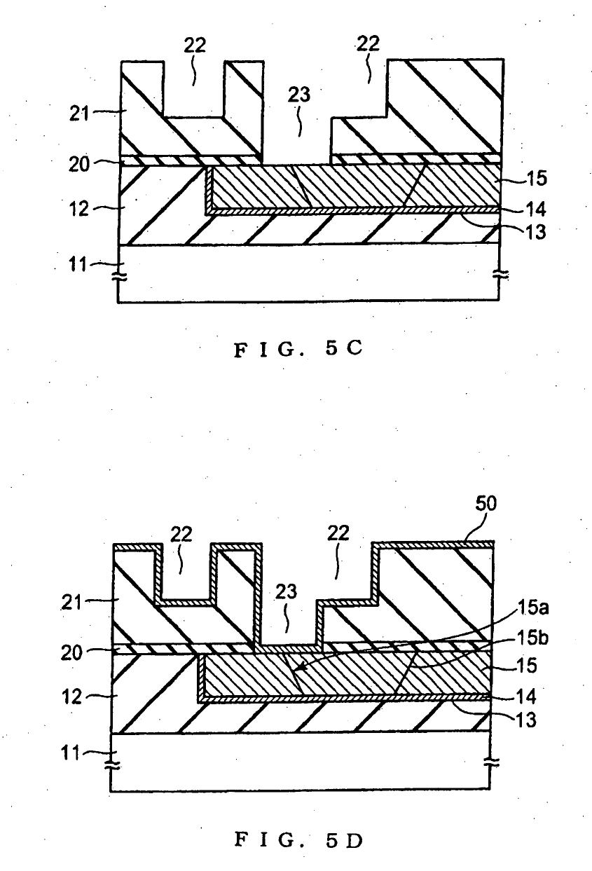

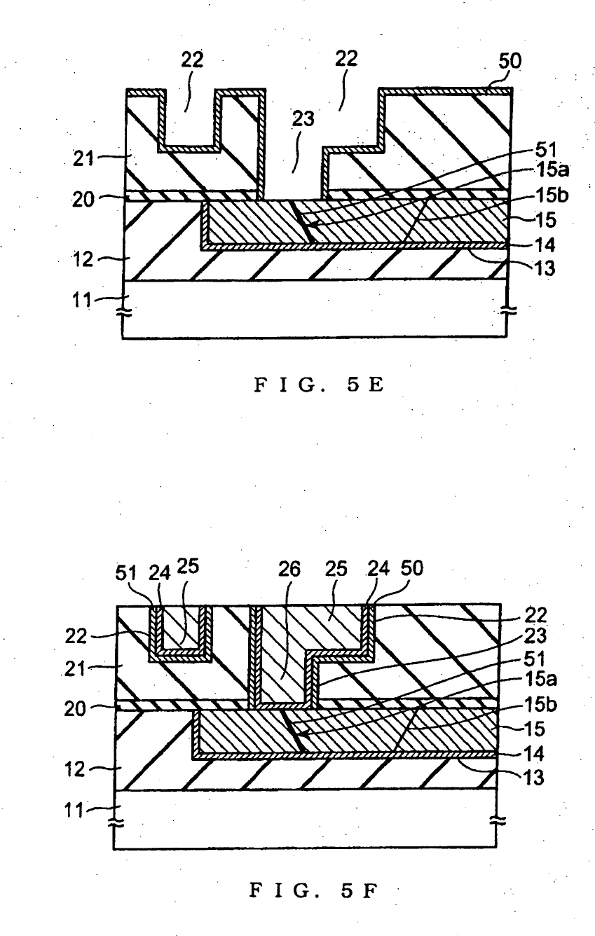

Next, a method of fabricating the semiconductor device according to this embodiment will be explained with reference to FIGS. 5A-5F.

First, the insulating film (not illustrated) is formed above the semiconductor substrate 11 having a circuit element therein. After forming a contact plug to connect to the circuit element, the first interlayer insulating film 12 composed of SiOC is formed on an entire surface of the insulating film by chemical vapor deposition (CVD) or the like and is removed by chemical mechanical polish (CMP) or the like for planarizing a surface of the first interlayer insulating film 12. The interconnection groove 13 for a first interconnection layer is formed on the first interlayer insulating film 12 by using lithography and etching or the like. The barrier metal layer 14 composed of Ta is formed on an entire surface of the first interlayer insulating film 12 and a Cu metal film is subsequently formed on the barrier metal layer 14 by electroplating. The Cu metal film is planarized by CMP to be filled in the interconnection groove 13. As a result, the first interconnection layer 15 composed of Cu is filled in the interconnection groove 13 via the barrier metal layer 14.

Next, the first diffusion barrier insulating film 20 composed of SiCN and the second interlayer insulating film 21 composed of SiOC is sequentially formed on an entire surface of the first interlayer insulating film 12 and the first interconnection layer 15 by CVD (FIG. 5B).

Successively, the interconnection groove 22, the interconnection groove 22 for a dual damascene structure and the via hole 23 for a dual damascene structure is formed in a layered film of the second interlayer insulating film 21 and the first diffusion barrier insulating film 20 on the first interconnection layer 15 by using lithography and anisotropic reactive-ion etching (RIE) (FIG. 5C).

The Al thin film 50 is formed on the inner side-wall of the via hole 23, the surface portion of the first interconnection layer 15 exposed in the via hole 23, the inner side-wall of the interconnection groove 22 and the second interlayer insulating film 21 by sputtering (FIG. 5D). The Al thin film 50 on the bottom surface in the via hole 23 has thickness of 30 nm. The semiconductor substrate 11 is heated at 330° C. to diffuse Al atoms from the Al thin film 50 formed at the bottom surface of the via hole 23 into the first interconnection layer 15. The semiconductor substrate 11 is successively cooled down to the room temperature, the Cu—Al intermetallic compound 51 is precipitated at the grain boundary 15a included in the portion of the first interconnection layer 15 exposed on the bottom surface of the via hole 23 (FIG. 5E).

The barrier metal layer 24 preventing Cu diffusion and a Cu film (not illustrated) as a seed for Cu electro-plating is sequentially formed on the Al thin film 50 by sputtering. Moreover, a Cu film is formed by electro-plating to fill in the interconnection groove 22 and the via hole 23.

The Cu film, the barrier metal film 24 and the Al thin film 50 expect in the interconnection groove 22 and the via hole 23 is removed by CMP to planarize the surface layer. The second interconnection layer 25 composed of Cu and the via plug 26 composed of Cu is formed in the interconnection groove 22 and in the via hole 23, respectively, the via plug 26 mutually connects between the first interconnection layer 15 and the second interconnection layer 25 (FIG. 5F).

The second diffusion barrier insulating film 27 and the third interlayer insulating film 28 are sequentially formed on the second interlayer insulating film 21 to finally obtain the semiconductor device as shown in FIG. 1. Furthermore, a Cu multilevel interconnection having an optional number of interconnection layers can be formed by repeating the processes as shown in FIG. 5C-5F.

According to the semiconductor device in this embodiment, the first material is selectively diffused into the grain boundary in the portion of the first interconnection layer beneath the via plug, as a result, the intermetallic compound composed of Cu—Al is formed in the grain boundary. Therefore, the grain boundary in the portion of the first interconnection layer beneath the via plug becomes stable, crystalline quality of the grain boundary is not deteriorated by performing a heat treatment. Since the thin film composed of the first material is formed between the inner side-wall of the via hole, this structure prevents degradation of adhesion strength between the barrier metal layer and the Cu via plug. Accordingly, adhesion strength at an interface between the barrier metal layer and the Cu via plug is sustained without additional processes. The suppression of the void growth by stress migration provides lowering the connecting failure between the interconnections.

In addition, a Cu—Al intermetallic compound is not formed in grain boundaries in the portion of the interconnection layer except the portion of the interconnection layer beneath the via hole, as a result, effective resistivity of the interconnection layer is not increased.

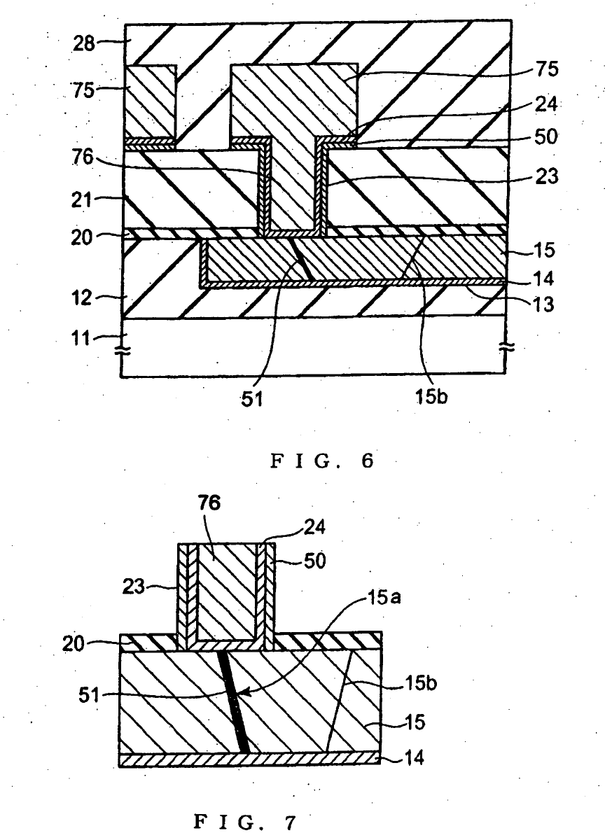

Next, a second embodiment of the present invention, which is a modification of the first embodiment, will be explained with reference to FIG. 6 and FIG. 7.

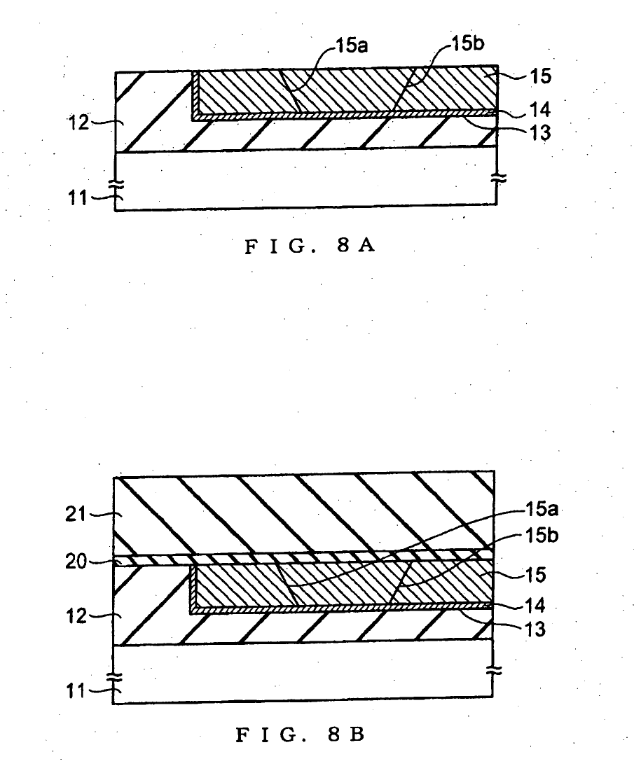

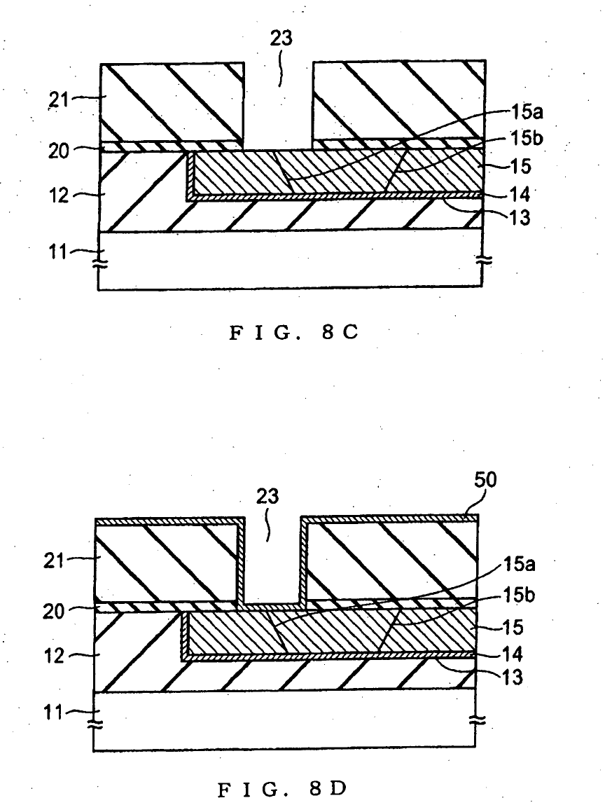

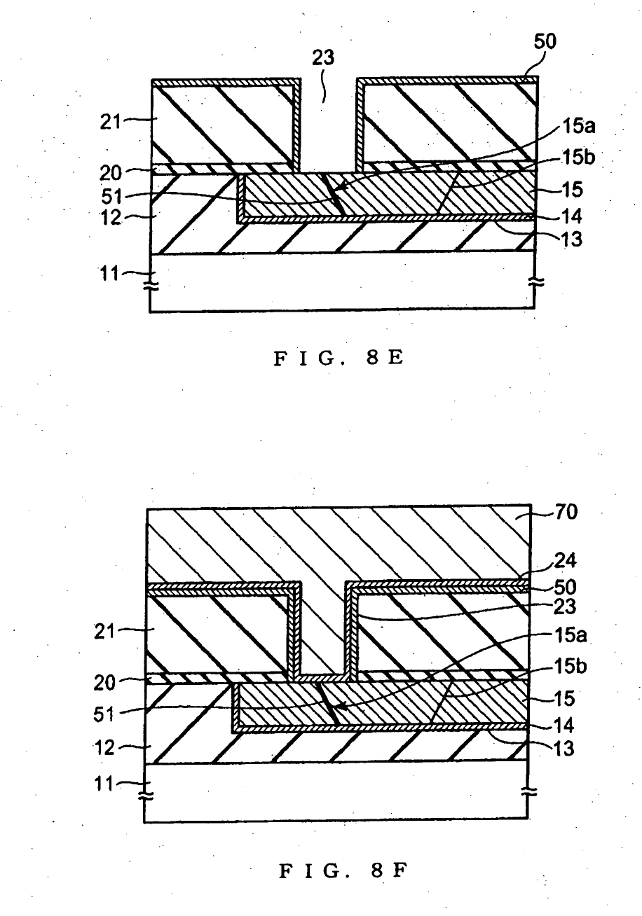

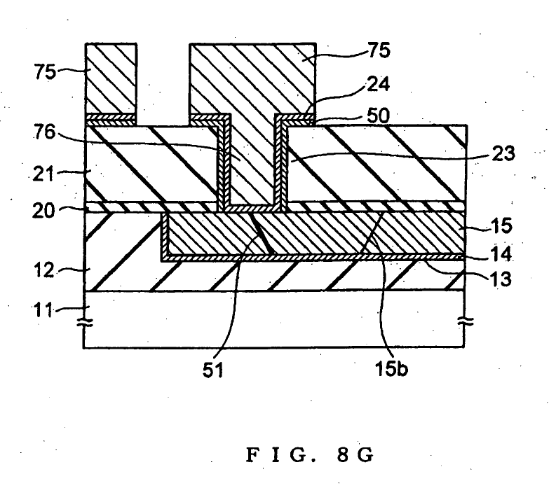

In FIGS. 8A-8B, a portion of a same composition as the first embodiment is attached the same number. Therefore, explanation on the same number in FIGS. 8A-8B of the second embodiment is omitted.

According to the semiconductor device in this embodiment as shown in FIG. 6, a second interconnection layer 75 and a via plug 76 is formed of a material mainly composed of Al instead of Cu. The via hole 23 is formed in the second interlayer insulating film 21. An Al—Cu alloy including Cu of 5 atomic % is filled in the via hole 23 via the Al thin film 50 and the barrier metal layer 24 formed on an inner side-wall of the via hole 23 to form the via plug 76. The second interconnection layer 75 composed of the Al—Cu alloy is integrally formed with the via plug 76 on the second interlayer insulating film 21 including the upper surface of the via plug 76 via the Al thin film 50 and the barrier metal layer 24. The third interlayer insulating film 28 is formed on the second interlayer insulating film 21 including the second interconnection layer 75.

In this embodiment as shown in FIG. 7, in order to prevent the void growth by stress migration, Al atoms of the Al thin film 50 is selectively diffused into the grain boundary 15a in the portion of the first interconnection layer 15 beneath the via plug 76 in the via hole 23 in the grain boundaries 15a, 15b of Cu composing the first interconnection layer 15. The Cu—Al intermetallic compound 51 is formed in the grain boundary 15a by the same method as the first embodiment.

Next, the method of fabricating the semiconductor device in this embodiment is explained with reference to FIG. 8A-8G. The processing steps in FIG. 8A to FIG. 8B are the same as those in FIG. 5A to FIG. 5B and explanation of the figures are omitted.

The first interlayer insulating film 12 is formed above the semiconductor substrate 11. The barrier metal layer 14 is formed on the first interlayer insulating film 12. The first interconnection layer 15 composed of Cu is formed on the barrier metal layer 14 to fill in the interconnection groove 13. A layered film of the first diffusion barrier insulating film 20 and the second interlayer insulating film 21 is formed on the first interlayer insulating film 12 and the first interconnection layer 15 (FIG. 8A, FIG. 8B). SiO₂ is used as the first interlayer insulating film 12 and the second interlayer insulating film 21 and SiN is used as the first diffusion barrier insulating film 20.

The via hole 23 is formed in the layered film of the second interlayer insulating film 21 and the first diffusion barrier insulating film 20 on the first interconnection layer 15 by using lithography and RIE or the like (FIG. 8C).

The Al thin film 50 is formed on the inner side-wall of the via hole 23, the surface of the first interconnection layer 15 exposed in the via hole 23 and the first interlayer insulating film 21 by sputtering (FIG. 8D). The Al thin film 50 on the bottom surface in the via hole 23 has a thickness of 30 nm. The semiconductor substrate 11 is heated at 330° C. to diffuse Al atoms from the Al thin film 50 on the bottom surface of the via hole 23 into the portion of the first interconnection layer 15. The semiconductor substrate 11 is successively cooled down to the room temperature, the Cu—Al intermetallic compound 51 is precipitates in the grain boundary 15a in the portion of the first interconnection layer 15 exposed on the bottom surface of the via hole 23 (FIG. 8E).

In order to prevent inter-diffusion between Al and Cu, the barrier metal layer 24 and an Al—Cu alloy 70 is sequentially formed by sputtering with heating (FIG. 8F). The heating temperature in forming the Al—Cu alloy 70 is 400° C. The Al—Cu alloy 70, the barrier metal layer 24 and the Al thin film 50 are delineated by using lithography and RIE. As a result, the second interconnection layer 75 composed of Al—Cu alloy is formed on the second interlayer insulating film 21 and the via plug 76 composed of Al—Cu alloy in the via hole 23 is formed to mutually connect between the first interconnection layer 15 and the second interconnection layer 75 (FIG. 8G).

Furthermore, the third interlayer insulating film 28 such as SiO₂ or the like is formed on the second interlayer insulating film 21 including the second interconnection layer 75 to finally obtain the semiconductor device as shown in FIG. 6.

Effects of the second embodiment also are the same as the effects of the first embodiment.

In the second embodiment, SiOC is used as the interlayer insulating film. However, the material of the interlayer insulating film is not limited to the SiOC film but a SiO₂ film or a porous low-k film or the like may be used. Furthermore, the interlayer insulating film can be formed by combining a plurality of the interlayer insulating materials.

In the first embodiment and the second embodiment in the present invention, sputtering is used as a method of forming the barrier metal or the like, however, CVD or ALD which is a modification of CVD can be also used as methods of forming films.

Moreover, Ta is used as the barrier metal layer; however, a metal material such as TaN, TiN, TiSiN, or WN and a layered structure being used the above metals also may be effective.

Other embodiments of the present invention will be apparent to those skilled in the art from consideration of the specification and practice of the invention disclosed herein. It is intended that the specification and example embodiments be considered as exemplary only, with a true scope and spirit of the invention being indicated by the claims that follow. The invention can be carried out by being variously modified within a range not deviated from the gist of the invention.

What is claimed is:

1. A semiconductor device, comprising:
a semiconductor substrate;
a first interconnection layer formed above the semiconductor substrate via a first interlayer insulating film, the first interconnection layer having Cu as a main material;
a second interconnection layer formed above the first interlayer insulating film and the first interconnection layer via a second interlayer insulating film; and
a via plug formed through the second interlayer insulating film, the via plug electrically connecting between the first interconnection layer and the second interconnection layer;
wherein a first material being different from Cu is selectively included in a grain boundary beneath the via plug among a plurality of grain boundaries included in the first interconnection layer.

2. The semiconductor device according to claim 1, further comprising:
a barrier metal layer formed between the second interconnection layer and the second interlayer insulating film and between the via plug and the second interlayer insulating film.

3. The semiconductor device according to claim 2, wherein a thin film including the first material is formed between the barrier metal layer and the second interlayer insulating film.

4. The semiconductor device according to claim 3, wherein the first material has a solubility limit concentration to Cu at least below 430° C. and the first material is transformed with Cu to an intermetallic compound above the solubility limit.

5. The semiconductor device according to claim 4, wherein t_{A} is given by
t_{A}≦t_{Cu}·(C_{Cu}/C_{A})·α/(100−α)
where t_{Cu} is a Cu thickness of the first interconnection layer, t_{A} is a thickness of the thin film including the first material beneath the second interconnection layer, C_{Cu} and C_{A} are atomic densities of Cu and the first material, respectively, and α presented as percentage is the solubility limit of the first material to Cu below 430° C.

6. The semiconductor device according to claim 1, wherein the second interconnection layer and the via plug have a dual damascene structure.

7. The semiconductor device according claim 1, further comprising:
a barrier metal layer formed between the first interlayer insulating film and the first interconnection layer.

8. The semiconductor device according to claim 1, wherein the second interconnection layer is Cu, Al or Al—Cu alloy.

9. The semiconductor device according to claim 1, wherein the first material is composed of Al, Si or Mg.

10. The semiconductor device according to claim 1, wherein at least one of the first interlayer insulating film and the second interlayer insulating film is composed of at least one of a SiOC film, a SiO₂ film, a poly-methyl siloxane film, a organic film, a fluorinated organic film or a porous Low-k film.

11. The semiconductor device according to claim 1, wherein at least one of the first interlayer insulating film or the second interlayer insulating film has a layered film.

12. A method of fabricating a semiconductor device, comprising:
forming a first interlayer insulating film above a semiconductor substrate;
forming a first interconnection layer having Cu as a main material in the first interlayer insulating film;
forming a second interlayer insulating film above the first interlayer insulating film and the first interconnection layer;
forming an interconnection groove in the second interlayer insulating film and a via hole through the second interlayer insulating film to a surface of the first interconnection layer, the via hole being junctually formed to the interconnection groove;
forming a thin film including a first material on an inner-wall of the interconnection groove, an inner-wall of the via hole and a surface portion of the first interconnection layer exposed in the via hole, the first material being different from Cu;
diffusing the first material into a grain boundary in a portion of the first interconnection layer exposed in the via hole;
forming a barrier metal layer on the thin film; and
filling an interconnection material in the interconnection groove and the via hole via the barrier metal layer to form a second interconnection layer in the interconnection groove and a via plug in the via hole.

13. The method of fabricating the semiconductor device according claim 12, further comprising:
forming an intermetallic compound composed of Cu and the first material in the grain boundary between diffusing the first material into the grain boundary and forming the barrier metal layer on the thin film.

14. The method of fabricating the semiconductor device according claim 13,
wherein diffusing the first material into the grain boundary includes carrying out a heat treatment below 430° C.

15. The method of fabricating the semiconductor device according claim 14, wherein t_{A} is given by
t_{A}≦t_{Cu}·(C_{Cu}/C_{A})·α/(100−α)
where t_{Cu} is a Cu thickness of the first interconnection layer, t_{A} is a thickness of the thin film including the first material beneath the second interconnection layer, C_{Cu} and C_{A} are atomic densities of Cu and the first material, respectively, and α presented as percentage is a solubility limit of the first material to Cu at the temperature of the heat treatment.

16. The method of fabricating the semiconductor device according claim 12, wherein the first material is composed of Al, Si or Mg.

17. A method of fabricating a semiconductor device, comprising:
forming a first interlayer insulating film above a semiconductor substrate;
forming a first interconnection layer having Cu as a main material in the first interlayer insulating film;
forming a second interlayer insulating film above the first interlayer insulating film and the first interconnection layer;
forming a via hole through the second interlayer insulating film to a surface of the first interconnection layer;
forming a thin film including a first material on an inner-wall of the via hole and a surface portion of the first interconnection layer exposed in the via hole, the first material being different from Cu;
diffusing the first material into a grain boundary in a portion of the first interconnection layer exposed in the via hole;
forming a barrier metal layer on the thin film; and
forming a via plug in the via hole and a second interconnection layer above the second interlayer insulating film via the barrier metal layer.

18. The method of fabricating the semiconductor device according claim 17 further comprising:
forming an intermetallic compound composed of Cu and the first material in the grain boundary between diffusing the first material into the grain boundary and forming the barrier metal layer on the thin film.

19. The method of fabricating the semiconductor device according claim 18
wherein diffusing the first material into the grain boundary includes carrying out a heat treatment below 430° C.

20. The method of fabricating the semiconductor device according claim 19 wherein t_{A} is given by
t_{A}≦t_{Cu}·(C_{Cu}/C_{A})·α/(100−α)
where t_{Cu} is a Cu thickness of the first interconnection layer, t_{A} is a thickness of the thin film including the first material beneath the second interconnection layer, C_{Cu} and C_{A} are atomic densities of Cu and the first material, respectively, and α presented as percentage is a solubility limit concentration of the first material to Cu at the temperature of the heat treatment.
